(19) United States
(12) Patent Application Publication
(10) Pub. No.: US 2023/0253931 A1
(43) Pub. Date: Aug. 10, 2023

(54) POWER AMPLIFIER SYSTEM WITH PROTECTION CIRCUITRY

(71) Applicant: Qorvo US, Inc., Greensboro, NC (US)

(72) Inventors: Grant Small, Nashua, NH (US); On S. A. Tang, Groton, MA (US); Jun Jadormio, Marlborough, MA (US)

(21) Appl. No.: 18/165,359

(22) Filed: Feb. 7, 2023

Related U.S. Application Data
(60) Provisional application No. 63/308,750, filed on Feb. 10, 2022.

(51) Int. Cl. H03F 1/52; H03F 3/24; H04B 1/04

(52) U.S. Cl. CPC H03F 1/523; H03F 3/245; H04B 1/04; H03F 2200/451; H03F 2200/318; H03F 2200/222; H03F 2200/387

(57) ABSTRACT

A power amplifier system is disclosed having a first stage amplifier that includes a first supply terminal, a first input, and a first output. A second stage amplifier has a second supply terminal, a second input, and a second output. A first stage bias circuitry has a bias output coupled to a bias input of the first stage amplifier and a bias control input. Absolute maximum ratings protection circuitry has a voltage monitoring input coupled to the second supply terminal and a bias control output coupled to the bias control input, wherein the absolute maximum ratings protection circuitry is configured to reduce the bias of the first stage amplifier through the bias control output based upon voltage monitored at the voltage monitoring input exceeding a predetermined voltage level. Additional absolute maximum ratings protection circuitry reduces the bias of the first stage amplifier if first stage amplifier supply voltage is excessive.

### RELATED APPLICATIONS

This application claims the benefit of provisional patent application Ser. No. 63/308,750, filed Feb. 10, 2022, the disclosure of which is hereby incorporated herein by reference in its entirety.

### FIELD OF THE DISCLOSURE

The present disclosure relates to protection circuitry for preventing damage to a power amplifier system that may be stressed at absolute maximum ratings.

### BACKGROUND

Traditionally, envelope tracking power amplifiers have modulated the first and second stage together at the same time. Since the voltages are the same for the power amplifiers, an absolute maximum ratings (AMR) circuit was placed on the first power supply voltage VCC1 that senses the first stage collector voltage and turns off the first stage bias to protect the power amplifier when VCC goes above voltages that might damage the power amplifier. Some envelope tracking system implementations are only modulating the second stage. In these systems the VCC1 and VCC2 voltages are at different levels. To prevent damage to the power amplifier in these implementations, protection circuitry is required that protects against excess voltage at either VCC1 or VCC2.

### SUMMARY

A power amplifier system is disclosed having a first stage amplifier that includes a first supply terminal, a first input, and a first output. A second stage amplifier has a second supply terminal, a second input, and a second output. A first stage bias circuitry has a bias output coupled to a bias input of the first stage amplifier and a bias control input. Also included is an absolute maximum ratings protection circuitry having a voltage monitoring input coupled to the second supply terminal and a bias control output coupled to the bias control input, wherein the absolute maximum ratings protection circuitry is configured to reduce the bias of the first stage amplifier through the bias control output based upon voltage monitored at the voltage monitoring input exceeding a predetermined voltage level. As a result, the second stage amplifier is protected from damage if voltage supplying the second stage amplifier exceeds the predetermined voltage level, which is at or below a maximum voltage specification for the second stage amplifier.

Additional absolute maximum ratings protection circuitry configured to monitor the voltage of the first stage is in parallel with absolute maximum ratings protection circuitry having a voltage monitoring input coupled to the second supply terminal. The additional absolute maximum ratings protection circuitry is configured to reduce the bias of the first stage amplifier through the bias control output based upon voltage monitored at a voltage monitoring input coupled to the first supply terminal exceeding another predetermined voltage level. As a result, the first stage amplifier is protected from damage if voltage supplying the first stage amplifier exceeds the predetermined voltage level, which is at or below a maximum voltage specification for the first stage amplifier. Placing both absolute maximum ratings protection circuitries in parallel is desirable for meeting ruggedness requirements in applications that require a separate VCC connection at the product level for first supply voltage VCC1 and the second supply voltage VCC2 where the two voltages may not operate at the same level in the customer applications.

Those skilled in the art will appreciate the scope of the present disclosure and realize additional aspects thereof after reading the following detailed description in association with the accompanying drawings.

### BRIEF DESCRIPTION OF THE DRAWINGS

The accompanying drawing figures incorporated in and forming a part of this specification illustrate several aspects of the disclosure and, together with the description, serve to explain the principles of the disclosure.

FIG. 1 is a circuit diagram showing a related-art power amplifier system that includes absolute maximum ratings protection circuitry according to the present disclosure.

FIG. 2 is a circuit diagram showing a power amplifier system that includes additional absolute maximum ratings protection circuitry according to the present disclosure.

FIG. 3 is a schematic of absolute maximum ratings circuitry that is structured in accordance with the present disclosure.

FIG. 4 is a schematic of first stage bias circuitry that is structured in accordance with the present disclosure.

FIGS. 5A, 5B, and 5C illustrate simulated first stage amplifier current varying the second stage amplifier supply voltage VCC2 while sweeping the first stage amplifier supply voltage VCC1 over temperature.

FIGS. 6A, 6B, and 6C illustrate simulated first-stage current varying first stage amplifier supply voltage VCC1 while sweeping the second stage amplifier supply voltage VCC2 over temperature.

FIGS. 7A, 7B, and 7C illustrate simulated first-stage current varying the first stage amplifier supply voltage VCC1 and the second stage amplifier supply voltage VCC2 simultaneously over temperature.

FIG. 8 is a diagram showing how the disclosed power amplifier system depicted in FIG. 2 may interact with user elements such as wireless communication devices.

### DETAILED DESCRIPTION

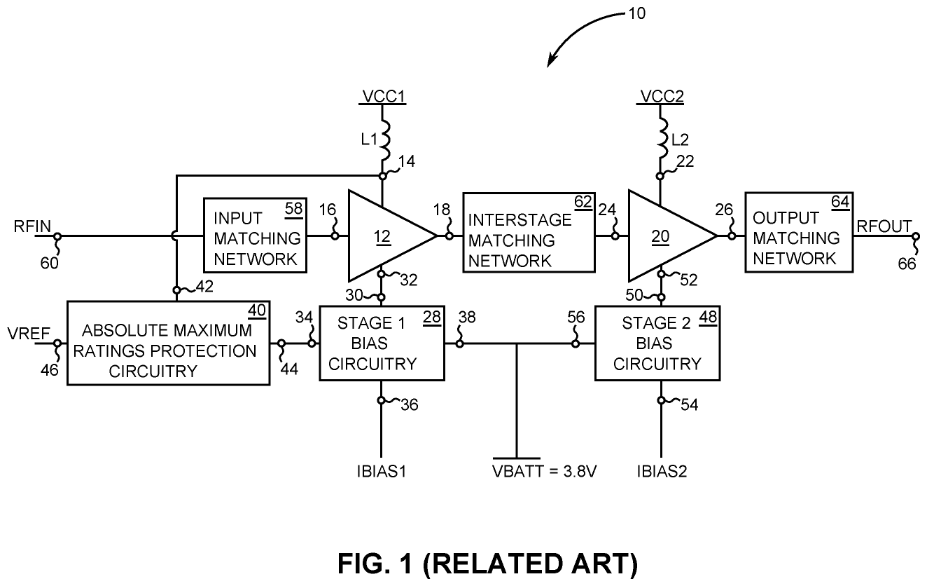

FIG. 1 is a circuit diagram of a related-art power amplifier system 10 having a first stage amplifier 12 that includes a first supply terminal 14, a first input 16, and a first output 18. A second stage amplifier 20 has a second supply terminal 22, a second input 24, and a second output 26. A first stage bias circuitry 28 has a bias output 30 coupled to a bias input 32 of the first stage amplifier 12 and a bias control input 34. The first stage bias circuitry 28 also has a bias current input 36 that receives a first bias current IBIAS1 and a bias supply voltage input 38 to which a battery source VBATT is coupled. A typical bias supply voltage is 3.8 V.

Also included is a first absolute maximum ratings protection circuitry 40 having a first voltage monitoring input 42 coupled to the first supply terminal 14 and a bias control output 44 coupled to the bias control input 34. The first absolute maximum ratings protection circuitry 40 is configured to reduce the bias of the first stage amplifier 12 through the bias control output 44 based upon voltage monitored at the voltage monitoring input 42 exceeding a predetermined voltage level. A voltage reference input 46 labeled VREF receives a reference voltage that may be scaled to establish a trigger threshold that is the predetermined voltage level that if exceeded by the monitored voltage indicates that an absolute maximum rating of the power amplifier system 10 has been exceeded. In some embodiments, the first absolute maximum ratings protection circuitry 40 shuts down the first stage amplifier 12 by bias pull-down until the absolute maximum ratings of the power amplifier system 10 are no longer exceeded. In other embodiments, the first absolute maximum ratings protection circuitry 40 reduces the bias to the first stage amplifier 12 to a safer level that avoids a complete shutdown of the first stage amplifier 12.

The power amplifier system 10 further includes a second stage bias circuitry 48 that has a bias output 50 coupled to a bias input 52 of the second stage amplifier 20. The second stage bias circuitry 48 also has a bias current input 54 that receives a second bias current IBIAS2 and a second bias supply voltage input 56 to which the battery source VBATT is coupled.

In the exemplary embodiment of the power amplifier system 10, an input matching network 58 is coupled between the first input 16 and an RF input 60 labeled RFIN. An interstage matching network 62 is coupled between the first output 18 and the second input 24, and an output matching network 64 is coupled between the second output 26 and an RF output 66 labeled RFOUT. Moreover, a first filter inductor L1 is coupled between the first supply terminal 14 and a first supply voltage source VCC1. A second filter inductor L2 is coupled between a second supply voltage source VCC2 and the second supply terminal 22.

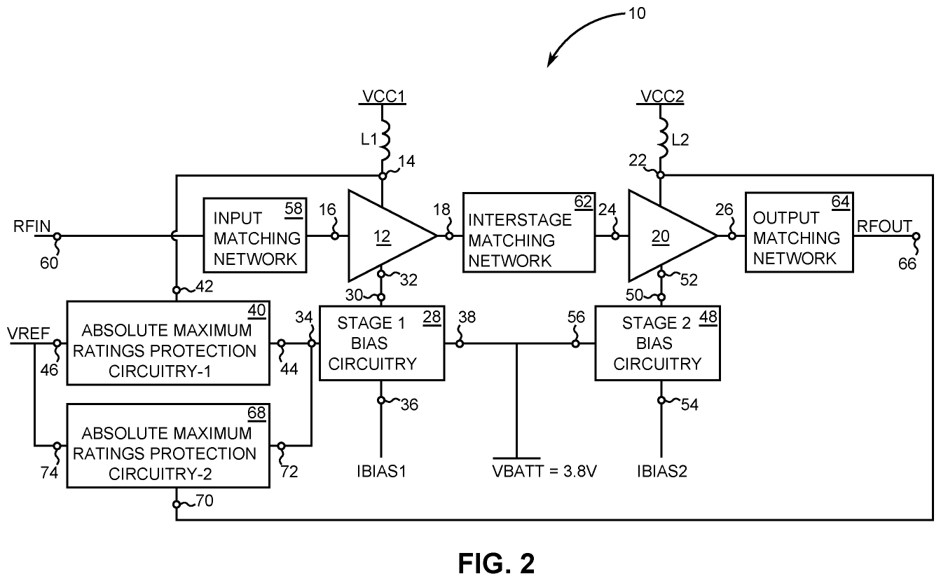

FIG. 2 is a circuit diagram showing the power amplifier system 10 that in accordance with the present disclosure includes additional absolute maximum ratings protection circuitry 68 that has a second voltage monitoring input 70, which is coupled to the second supply terminal 22. A second bias control output 72 is coupled to the bias control input 34. A second voltage reference input 74 receives the reference voltage VREF that may be scaled to establish a second trigger threshold that is another predetermined voltage level that if exceeded by the second monitored voltage indicates that an absolute maximum rating of the power amplifier system 10 has been exceeded.

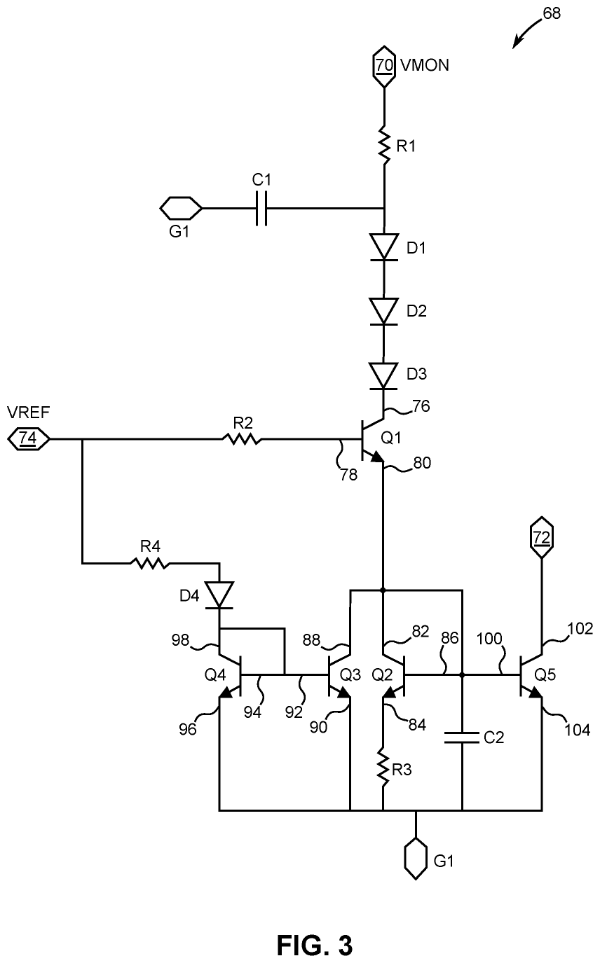

FIG. 3 is a simplified schematic of an exemplary embodiment of the absolute maximum ratings protection circuitry 68. A first transistor Q1 has a first collector 76 coupled to the second voltage monitoring input 70 through a series stack of diodes D1, D2, and D3 and a first resistor R1. A first capacitor C1 is coupled between the fixed voltage node G1 and a node between the first resistor and the series stack of diodes D1, D2, and D3. The first resistor R1 and the first capacitor C1 are configured to filter radio frequency components from a second monitored voltage VMON at the second voltage monitoring input 70. A first base 78 of the first transistor Q1 is coupled to the second voltage reference input 74 through a second resistor R2, and a first emitter 80 is coupled to a second collector 82 of a second transistor Q2, which has a second emitter 84 coupled to the fixed voltage node G1 through a third resistor R3. A base 86 of the second transistor Q2 is coupled to the second collector 82. A third transistor Q3 has a third collector 88 coupled to the second collector 82, and a third emitter 90 coupled to the fixed voltage node G1. A third base 92 of the third transistor Q3 is coupled to a fourth base 94 of a fourth transistor Q4, which has a fourth emitter 96 coupled to the fixed voltage node G1. A fourth collector 98 is coupled to the second voltage monitoring input 74 through a fourth diode D4 that is coupled in series with a fourth resistor R4. A fifth transistor Q5 has a fifth base 100 that is coupled to the second base 86 of the transistor Q2. The fifth base 100 is also coupled to the fixed voltage node G1 through a second capacitor C2 to provide filtering of residual RF signal components. The fifth transistor Q5 has a fifth collector 102 coupled to the second bias control output 72 and a fifth emitter 104 coupled to the fixed voltage node G1.

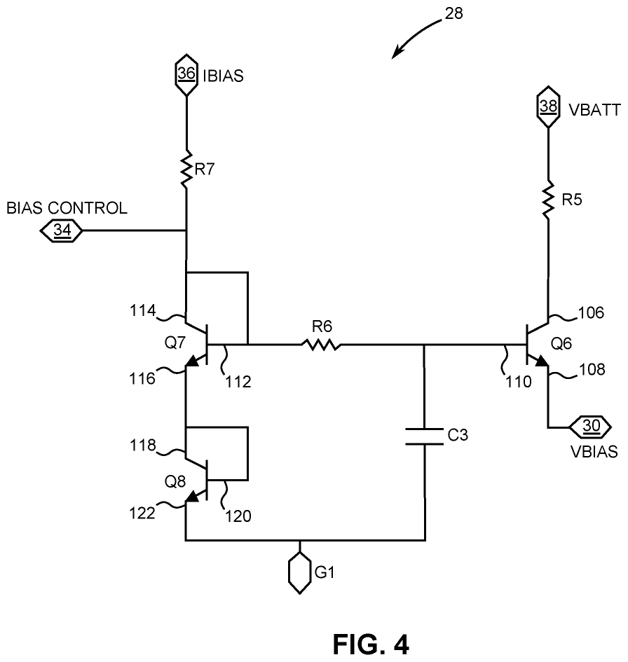

FIG. 4 is a simplified schematic of an exemplary embodiment of the first stage bias circuitry 28 that is structured in accordance with the present disclosure. The first stage bias circuitry 28 includes a sixth transistor Q6 that has a sixth collector 106 coupled to the bias supply voltage input 38 through a fifth resistor R5 and a sixth emitter 108 coupled to the bias output 30. A sixth base 110 is coupled through a sixth resistor R6 to an seventh base 112 of a seventh transistor Q7. The sixth base 110 of the sixth transistor Q6 is also coupled to the fixed voltage node G1 through a third capacitor C3 to provide filtering of residual RF signal components. A seventh collector 114 of the seventh transistor Q7 is coupled to both the seventh base 112 and the bias control input 34. A seventh resistor R7 couples the seventh collector 114 to the bias current input 36 that receives the first bias current IBIAS1. A seventh emitter 116 of the seventh transistor Q7 is coupled to an eighth collector 118 of an eighth transistor Q8, which has an eighth base 120 that is coupled to the eighth collector 118. An eighth emitter 122 of the eighth transistor Q8 is coupled to the fixed voltage node G1, which in this exemplary embodiment is ground. During operation, a bias pull-down through the bias control input 34 executed by either of the first absolute maximum ratings protective circuitry 40 or the second absolute maximum ratings circuitry 68 causes the bias on the sixth transistor Q6 to reduce precipitously, which in turn drastically reduces or shuts off completely the bias current flowing through the bias output 30 supplying bias to the first stage amplifier 12. As a result, both the first stage amplifier 12 and the second stage amplifier 20 are protected from supply voltage overages to either of the first stage amplifier 12 or the second stage amplifier 20.

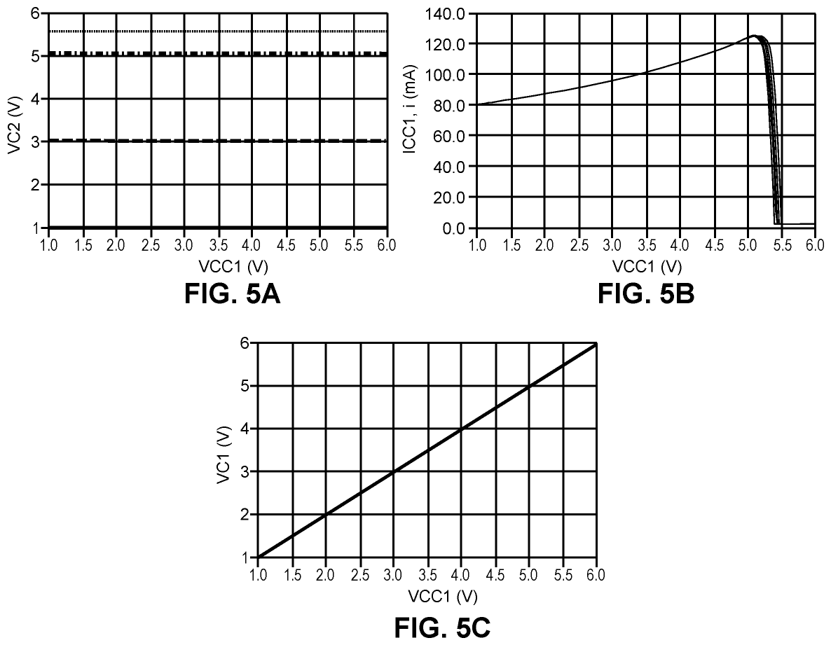

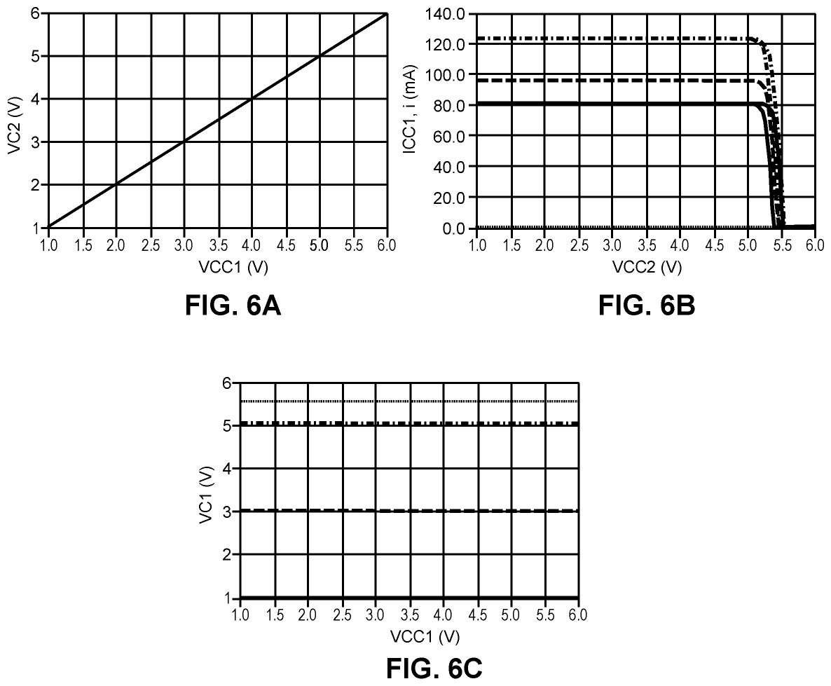

FIGS. 5A, 5B, and 5C illustrate simulated first stage amplifier current varying the second stage amplifier supply voltage VCC2 while sweeping the first stage amplifier supply voltage VCC1 over temperature. FIGS. 6A, 6B, and 6C illustrate simulated first stage amplifier current varying first stage amplifier supply voltage VCC1 while sweeping the second stage amplifier supply voltage VCC2 over temperature. Simulation results shown in FIGS. 5A, 5B, and 5C and FIGS. 6A, 6B, and 6C show that the bias pull-down is consistent at 5.2 V when either the first stage amplifier supply voltage VCC1 or the second stage supply voltage VCC2 is greater than either predetermined threshold voltage. FIGS. 5A, 5B, and 5C and FIGS. 6A, 6B, and 6C also illustrate that bias pull-down is unaffected by safe levels of supply voltage for either the first stage amplifier supply voltage VCC1 or the second stage supply voltage VCC2.

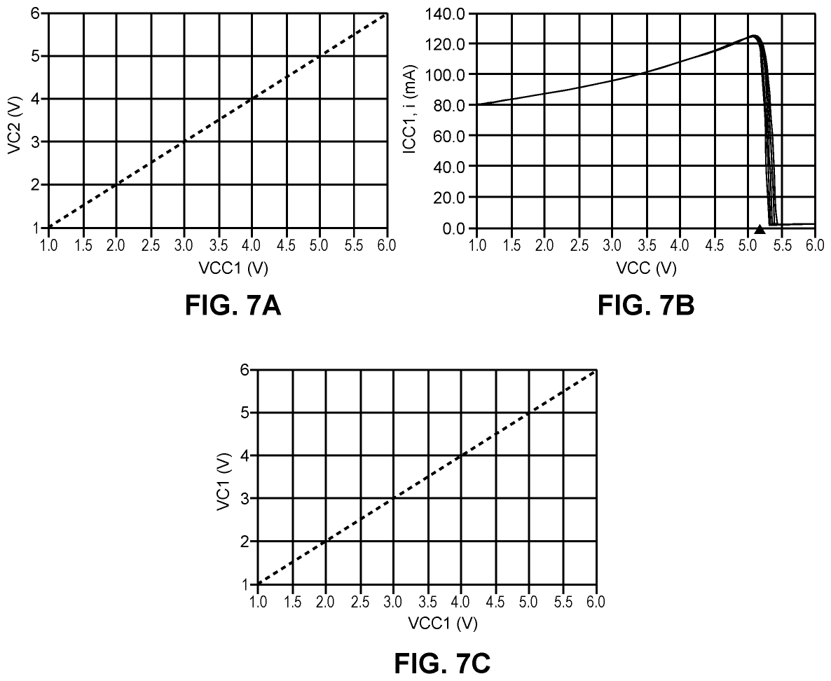

FIGS. 7A, 7B, and 7C illustrate simulated first stage amplifier current varying the first stage amplifier supply voltage VCC1 and the second stage amplifier supply voltage VCC2 simultaneously over temperature. Moreover, FIGS. 7A, 7B, and 7C show simulated behavior when sweeping the first stage amplifier supply voltage VCC1 and the second stage amplifier supply VCC2 together. Also, the FIGS. 7A, 7B, and 7C show the same trigger voltage as sweeping the VCC voltages independently.

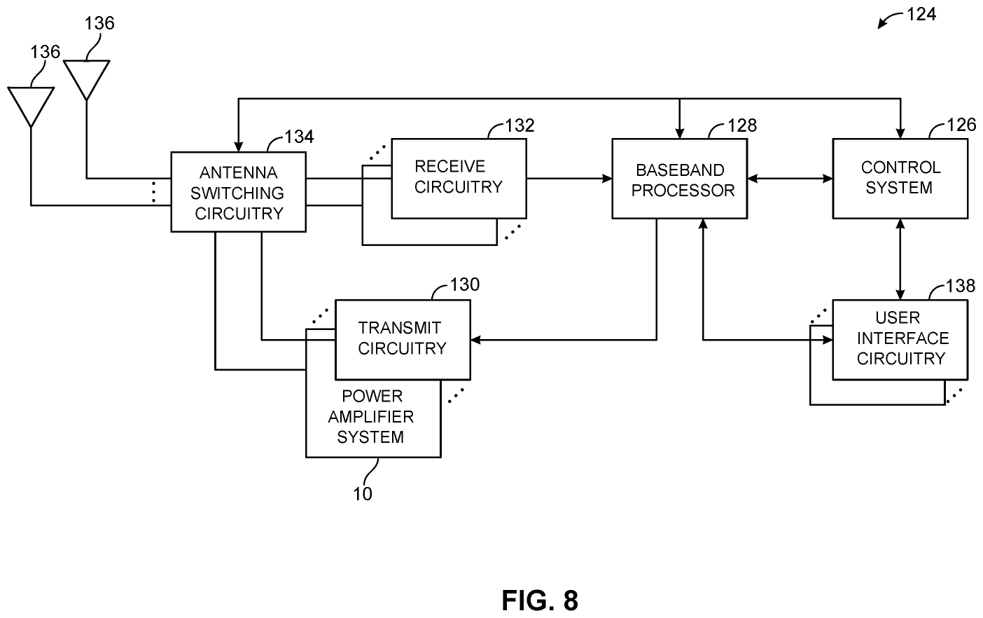

With reference to FIG. 8, the concepts described above may be implemented in various types of wireless communication devices or user elements 124, such as mobile terminals, smart watches, tablets, computers, navigation devices, access points, and the like that support wireless communications, such as cellular, wireless local area network (WLAN), Bluetooth, and near-field communications. The user elements 124 will generally include a control system 126, a baseband processor 128, transmit circuitry 130 that includes the power amplifier system 10 (FIG. 2), receive circuitry 132, antenna switching circuitry 134, multiple antennas 136, and user interface circuitry 138. The receive circuitry 132 receives radio frequency signals via the antennas 136 and through the antenna switching circuitry 134 from one or more basestations. A low-noise amplifier and a filter cooperate to amplify and remove broadband interference from the received signal for processing.

Downconversion and digitization circuitry (not shown) will then downconvert the filtered, received signal to an intermediate or baseband frequency signal, which is then digitized into one or more digital streams.

The baseband processor 128 processes the digitized received signal to extract the information or data bits conveyed in the received signal. This processing typically comprises demodulation, decoding, and error correction operations. The baseband processor 128 is generally implemented in one or more digital signal processors and application-specific integrated circuits.

For transmission, the baseband processor 128 receives digitized data, which may represent voice, data, or control information, from the control system 126, which it encodes for transmission. The encoded data is output to the transmit circuitry 130, where it is used by a modulator to modulate a carrier signal that is at a desired transmit frequency or frequencies. A power amplifier will amplify the modulated carrier signal to a level appropriate for transmission and deliver the modulated carrier signal to the antennas 136 through the antenna switching circuitry 134 to the antennas 136. The antennas 136 and the replicated transmit and receive circuitries 130, 132 may provide spatial diversity. Modulation and processing details will be understood by those skilled in the art.

Those skilled in the art will recognize improvements and modifications to the present disclosure. All such improvements and modifications are considered within the scope of the concepts disclosed herein.

What is claimed is:

1. A power amplifier system comprising:
a first stage amplifier having a first supply terminal, a first input, and a first output;
a second stage amplifier having a second supply terminal, a second output, and a second input coupled to the first output;
a first stage bias circuitry having a bias output coupled to a bias input of the first stage amplifier and a bias control input; and
absolute maximum ratings protection circuitry having a voltage monitoring input coupled to the second supply terminal and a bias control output coupled to the bias control input, wherein the absolute maximum ratings protection circuitry is configured to reduce the bias of the first stage amplifier through the bias control output based upon voltage monitored at the voltage monitoring input exceeding a predetermined voltage level.

2. The power amplifier system of claim 1 wherein the predetermined voltage level is at or below a maximum voltage specification for the second stage amplifier.

3. The power amplifier system of claim 2 wherein the absolute maximum ratings protection circuitry has a voltage reference input configured to receive a reference voltage from which the predetermined voltage level is derived.

4. The power amplifier system of claim 3 wherein the absolute maximum ratings protection circuitry comprises:
a first transistor having a first collector coupled to the voltage monitoring input through a series stack of diodes and a first resistor, a first emitter, and a first base coupled to the voltage reference input; and
a second transistor having a second collector coupled to the bias control output, a second base coupled to the first emitter, and a second emitter coupled to a fixed voltage node.

5. The power amplifier system of claim 4 wherein the absolute maximum ratings protection circuitry further comprises a filter capacitor coupled between the second base and the fixed voltage node.

6. The power amplifier system of claim 5 wherein the absolute maximum ratings protection circuitry further comprises a third transistor having a third collector coupled to the second emitter, a third base coupled to the second base, and a third emitter coupled to the fixed voltage node through a second resistor.

7. The power amplifier system of claim 6 wherein the absolute maximum ratings protection circuitry further comprises:
a fourth transistor having a fourth collector coupled to the second emitter, a fourth base, and a fourth emitter coupled to the fixed voltage node; and
a fifth transistor having a fifth collector and a fifth base coupled to both the fifth collector and the fourth base, and a fifth emitter coupled to the fixed voltage node, wherein the fifth collector is coupled to the voltage reference input, a second resistor, and a diode coupled in series.

8. The power amplifier system of claim 7 wherein the fixed voltage node is ground.

9. The power amplifier system of claim 1 further comprising additional absolute maximum ratings protection circuitry having an additional voltage monitoring input coupled to the first supply terminal and an additional bias control output coupled to the bias control input, wherein the additional absolute maximum ratings protection circuitry is configured to reduce the bias of the first stage amplifier through the bias control output based upon voltage monitored at the additional voltage monitoring input exceeding an additional predetermined voltage level.

10. The power amplifier system of claim 9 wherein the additional predetermined voltage level is at or below a maximum voltage specification for the first stage amplifier.

11. The power amplifier system of claim 10 wherein the additional absolute maximum ratings protection circuitry has an additional voltage reference input configured to receive the reference voltage from which the additional predetermined voltage level is derived.

12. A wireless communication device comprising:
a baseband processor;
transmit circuitry configured to receive encoded data from the baseband processor and to modulate a carrier signal with the encoded data, wherein the transmit circuitry comprises:
a first stage amplifier having a first supply terminal, a first input, and a first output;
a second stage amplifier having a second supply terminal, a second output, and a second input coupled to the first output;
a first stage bias circuitry having a bias output coupled to a bias input of the first stage amplifier and a bias control input; and
absolute maximum ratings protection circuitry having a voltage monitoring input coupled to the second supply terminal and a bias control output coupled to the bias control input, wherein the absolute maximum ratings protection circuitry is configured to reduce the bias of the first stage amplifier through the bias control output based upon voltage monitored at the voltage monitoring input exceeding a predetermined voltage level.

13. The wireless communication device of claim 12 wherein the predetermined voltage level is at or below a maximum voltage specification for the second stage amplifier.

14. The wireless communication device of claim 13 wherein the absolute maximum ratings protection circuitry has a voltage reference input configured to receive a reference voltage from which the predetermined voltage level is derived.

15. The wireless communication device of claim 14 wherein the absolute maximum ratings protection circuitry comprises:
a first transistor having a first collector coupled to the voltage monitoring input through a series stack of diodes and a first resistor, a first emitter, and a first base coupled to the voltage reference input; and
a second transistor having a second collector coupled to the bias control output, a second base coupled to the first emitter, and a second emitter coupled to a fixed voltage node.

16. The wireless communication device of claim 15 wherein the absolute maximum ratings protection circuitry further comprises a filter capacitor coupled between the second base and the fixed voltage node.

17. The wireless communication device of claim 16 wherein the absolute maximum ratings protection circuitry further comprises a third transistor having a third collector coupled to the second emitter, a third base coupled to the second base, and a third emitter coupled to the fixed voltage node through a second resistor.

18. The wireless communication device of claim 17 wherein the absolute maximum ratings protection circuitry further comprises:
a fourth transistor having a fourth collector coupled to the second emitter, a fourth base, and a fourth emitter coupled to the fixed voltage node; and
a fifth transistor having a fifth collector and a fifth base coupled to both the fifth collector and the fourth base, and a fifth emitter coupled to the fixed voltage node, wherein the fifth collector is coupled to the voltage reference input, a second resistor, and a diode coupled in series.

19. The power amplifier system of claim 18 wherein the fixed voltage node is ground.

20. The power amplifier system of claim 12 further comprising additional absolute maximum ratings protection circuitry having an additional voltage monitoring input coupled to the first supply terminal and an additional bias control output coupled to the bias control input, wherein the additional absolute maximum ratings protection circuitry is configured to reduce the bias of the first stage amplifier through the bias control output based upon voltage monitored at the additional voltage monitoring input exceeding an additional predetermined voltage level.

21. The power amplifier system of claim 20 wherein the additional predetermined voltage level is at or below a maximum voltage specification for the first stage amplifier.

22. The power amplifier system of claim 21 wherein the additional absolute maximum ratings protection circuitry has an additional voltage reference input configured to receive the reference voltage from which the additional predetermined voltage level is derived.

23. A method of operating a power amplifier system having a first stage amplifier with bias circuitry and a first supply terminal, a second stage amplifier, a second supply terminal, and absolute maximum ratings protection circuitry having a voltage monitoring input coupled to the second supply terminal and a bias control output coupled to the bias circuitry, the method comprising:
monitoring voltage at the voltage monitoring input by way of the absolute maximum ratings protection circuitry; and
reducing the bias of the first stage amplifier absolute maximum ratings protection circuitry through the bias control output based upon voltage monitored at the voltage monitoring input exceeding a predetermined voltage level.

24. The method of operating a power amplifier system of claim 23 further comprising:
monitoring voltage at the first supply terminal by way of another absolute maximum ratings protection circuitry having another bias control output; and
reducing the bias of the first stage amplifier absolute maximum ratings protection circuitry through the another bias control output based upon voltage monitored at the first supply terminal exceeding another predetermined voltage level.
